(19) United States
(12) Patent Application Publication
(10) Pub. No.: US 2025/0151591 A1
(43) Pub. Date: May 8, 2025

(54) DISPLAY DEVICE

(71) Applicant: LG Display Co., Ltd., Seoul (KR)

(72) Inventors: DongMin Jang, Paju-si (KR); Sungwoo Jun, Paju-si (KR)

(73) Assignee: LG Display Co., Ltd., Seoul (KR)

(21) Appl. No.: 18/935,963

(22) Filed: Nov. 4, 2024

(30) Foreign Application Priority Data
Nov. 8, 2023 (KR) 10-2023-0153436

(51) Int. Cl. H10K 59/80; H10K 59/38; H10K 59/40

(52) U.S. Cl. CPC H10K 59/8792; H10K 59/38; H10K 59/40

(57) ABSTRACT

A display device includes: a substrate including a plurality of light emitting areas and a plurality of non-light emitting areas respectively between the light emitting areas; a first buffer layer over the substrate; a plurality of color filters on the first buffer layer and respectively over the light emitting areas, the color filters being spaced apart from each other; a bridge on the first buffer layer in a space between two adjacent color filters among the color filters; an insulating layer covering the first buffer layer, the color filters, and the bridge, and having a first recessed portion over the bridge in the space between the two adjacent color filters; a touch sensor in the first recessed portion of the insulating layer; and a black matrix covering the touch sensor in the first recessed portion of the insulating layer.

### CROSS-REFERENCE TO RELATED APPLICATION

This application claims the priority benefit of Republic of Korea Patent Application No. 10-2023-0153436, filed on Nov. 8, 2023, in the Korean Intellectual Property Office, which is incorporated herein by reference for all purposes as if fully set forth herein.

### BACKGROUND

### Technical Field

The present disclosure relates to electronic devices, and more specifically, to display devices.

### Description of Related Art

As the information-oriented society has developed, the display technology has rapidly progressed to meet various needs for visually expressing information, data, applications, and the like. Indeed, various types of display devices with excellent characteristics and performance, such as a slim package, light weight, low power consumption, and the like, have been developed.

For example, liquid crystal display (LCD) devices, plasma display panel (PDP) devices, quantum dot (QD) display devices, organic light emitting diode (OLED) display devices, field emission display (FED) devices, and the like have become increasingly popular.

Display devices increasingly employ a touch-based input function that enables users to easily input information or a command to the display devices in an intuitive and convenient manner, in addition to implementing a function of displaying images or data. To provide such a touch-based input function, the display devices may include one or more touch sensors. For example, touch sensors may be manufactured in the form of a touch panel and thereafter attached to a display panel during the process of manufacturing a corresponding display device. Recently, to simplify the process of manufacturing of a display device with a touch function and to reduce manufacturing costs, touch sensors have been increasingly embedded in a display panel of the display device.

Where touch sensors include a metal, external light entering the display device may be reflected by the touch sensors, potentially leading to reduced image quality. To address this issue, a black matrix may be disposed on touch sensors. However, in this implementation, a step difference may occur in the black matrix due to the height of the touch sensor. That is, because the black matrix is formed to have a smaller height (or thickness) in an area where one or more touch sensors are disposed than in an area where a touch sensor is not disposed, there may arise a problem in that the reflectance of the area of the black matrix with the smaller height may increase.

### SUMMARY

The present disclosure is directed to a display device that substantially obviates one or more of the problems due to limitations and disadvantages of the related art.

To address these issues, one or more aspects of the present disclosure may provide a display device including a structure where a touch sensor and a black matrix are disposed in a space between the color filters, and thereby provide a reduced reflectance by forming the black matrix at a desired height in an area where the touch sensor is disposed without increasing the overall size of the display device.

One or more aspects of the present disclosure may provide a display device including a structure where a height of a recessed portion where a touch sensor and a black matrix are disposed is adjustable by controlling a height of color filters, thereby enabling the black matrix to be disposed at a desired target height.

One or more aspects of the present disclosure may provide a display device including a structure where a height of a black matrix covering a touch sensor including a metal may be disposed at a desired target height, thereby providing advantages of reducing reflectance and preventing reduction in image quality.

To achieve these objects and other advantages of the present disclosure, as embodied and broadly described herein, a display device may include: a base substrate including a plurality of light emitting areas and a plurality of non-light emitting areas; a plurality of light emitting elements on the base substrate and respectively in the plurality of light emitting areas; an encapsulation layer on the plurality of light emitting elements; a first buffer layer on the encapsulation layer; a plurality of color filters on the first buffer layer and respectively over the plurality of light emitting areas, the plurality of color filters being spaced apart from each other; a bridge on the first buffer layer in a space between two adjacent color filters among the plurality of color filters, the bridge being disposed over one of the plurality of non-light emitting areas; an insulating layer covering the first buffer layer, the plurality of color filters, and the bridge, and including a first recessed portion over the bridge in the space between the two adjacent color filters; a touch sensor in the first recessed portion of the insulating layer; and a black matrix covering the touch sensor in the first recessed portion of the insulating layer.

In another aspect of the present disclosure, a display device may include: a substrate including a plurality of light emitting areas and a plurality of non-light emitting areas respectively between the light emitting areas; a first buffer layer over the substrate; a plurality of color filters on the first buffer layer and respectively over the light emitting areas, the color filters being spaced apart from each other; a bridge on the first buffer layer in a space between two adjacent color filters among the color filters; an insulating layer covering the first buffer layer, the color filters, and the bridge, and having a first recessed portion over the bridge in the space between the two adjacent color filters; a touch sensor in the first recessed portion of the insulating layer; and a black matrix covering the touch sensor in the first recessed portion of the insulating layer.

In one or more aspects of the present disclosure, a display device may include a structure where a touch sensor and a black matrix are disposed in a space between the color filters, and thereby provide a reduced reflectance by forming the black matrix at a desired height in an area where the touch sensor is disposed without increasing the overall size of the display device.

In one or more aspects of the present disclosure, a display device may include a structure where a height of a recessed portion where a touch sensor and a black matrix are disposed is adjustable by controlling a height of color filters, thereby enabling the black matrix to be disposed at a desired target height.

In one or more aspects of the present disclosure, a display device may include a structure where a height of a black matrix covering a touch sensor including a metal may be disposed at a desired target height, thereby providing advantages of reducing reflectance and preventing reduction in image quality.

In one or more aspects of the present disclosure, a display device may include a structure where reflection of external light can be reduced even without a polarizer, thereby providing an advantage of the display device with a lighter weight.

The advantages and effects according to the present disclosure are not limited to those described above, and additional advantages and effects are included in or may be obtained from the present disclosure.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed without limiting the claims.

### BRIEF DESCRIPTION OF THE DRAWINGS

The accompanying drawings, which are included to provide a further understanding of the disclosure and are incorporated in and constitute a part of the disclosure, illustrate aspects and example embodiments of the disclosure and together with the description serve to explain principles of the disclosure. In the drawings:

FIG. 1 illustrates a system configuration of a display device according to example embodiments of the present disclosure;

FIG. 2 is an example plan view of a display device according to example embodiments of the present disclosure;

FIG. 3 is an example cross-sectional view taken along line A-A′ of the display device shown in FIG. 2;

FIG. 4 is a cross-sectional view illustrating a display device according to a comparative example where a TOE process and a COE process are sequentially performed; and

FIGS. 5 to 9 are example cross-sectional views illustrating display devices according to example embodiments of the present disclosure.

### DETAILED DESCRIPTION

Reference will now be made in detail to various embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

In the following description, where a detailed description of a relevant known function or configuration may unnecessarily obscure aspects of the present disclosure, a detailed description of such known function or configuration may be omitted.

The shapes, sizes, ratios, angles, numbers, and the like, which are illustrated in the drawings to describe various example embodiments of the present disclosure, are merely given by way of example. Therefore, the present disclosure is not limited to the illustrations in the drawings.

Terms like “including,” “having,” “containing,” “constituting,” “made up of,” and “formed of” used herein are generally intended to allow inclusion or addition of one or more other components unless the terms are used with a more limiting term, such as “only” or the like. As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order, sequence, precedence, or number of such elements. These terms are used only to refer to one element separately from another. For example, a first element could be termed a second element, and a second element could similarly be termed a first element, without departing from the scope of the present disclosure.

Where an expression that an element or layer “is connected to,” “is coupled to,” “is adhered to,” “contacts,” or “overlaps” another element or layer is used, the element or layer not only can be directly connected, coupled, or adhered to or directly contact or overlap another element or layer, but also can be indirectly connected, coupled, or adhered or indirectly contact or overlap another element or layer with one or more intervening elements or layers “disposed” or “interposed” between the elements or layers, unless otherwise specified.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is described as disposed “on” another element or layer, a third element or layer may be interposed therebetween. Furthermore, the terms “left,” “right,” “top,” “bottom,” “downward,” “upward,” “upper,” “lower,” and the like refer to an arbitrary frame of reference.

In addition, where any dimensions, relative sizes, and the like are discussed, numerical values for an elements or features, or corresponding information (e.g., level, range, etc.) should be considered to include a tolerance or error range that may be caused by various factors (e.g., process factors, internal or external impact, noise, etc.) even where no explicit description of such a tolerance or error range is provided. Further, the term “may” fully encompasses all the meanings of the term “can”.

Hereinafter, with reference to the accompanying drawings, various example embodiments of the present disclosure will be described in detail.

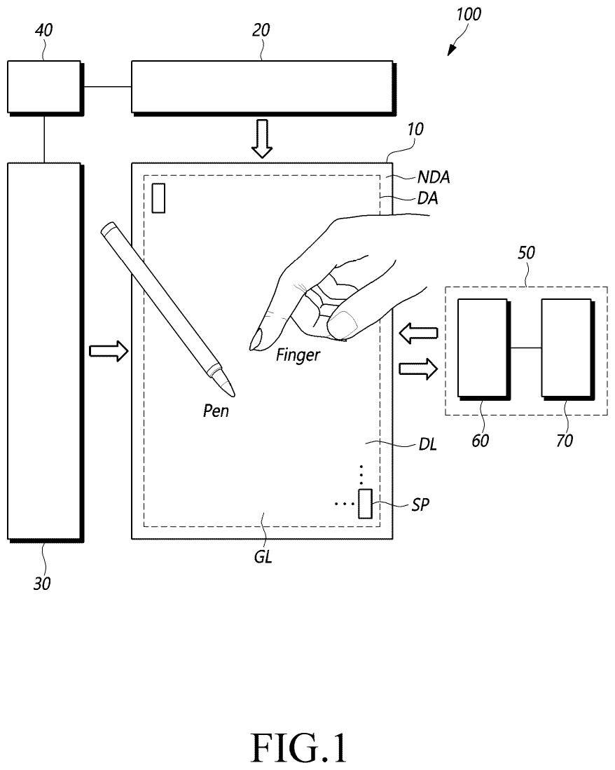

FIG. 1 illustrates a system configuration of a display device 100 according to example embodiments of the present disclosure.

As shown in FIG. 1, in one or more example embodiments, the display device 100 may include a display panel 10 and a display driving circuit for driving the display panel 10 as components for displaying images.

The display driving circuit may include a data driving circuit 20, a gate driving circuit 30, and a display controller 40.

The display panel 10 may include a display area DA configured to display an image and a non-display area NDA where an image is not displayed. The non-display area NDA may be an area outside of the display area DA and may also be referred to as a bezel or a bezel area. All or at least a portion of the non-display area NDA may be an area visible from the front surface of the display device 100, or an area that is bent and invisible from the front surface of the display device 100.

The display panel 10 may include a plurality of subpixels SP. The display panel 10 may further include various types of signal lines to drive the plurality of subpixels SP.

In one or more aspects, the display device 100 may be a liquid crystal display device or the like, or may be a self-emission display device in which light is emitted from the display panel 10 itself. Where the display device 100 according to example embodiments of the present disclosure is the self-emission display device, each of the plurality of subpixels SP may include a light emitting element.

For example, the display device 100 according to example embodiments of the present disclosure may be an organic light emitting display device implemented with organic light emitting diodes (OLED) as light emitting elements. In another example, the display device 100 according to aspects of the present disclosure may be an inorganic light emitting display device implemented with inorganic material-based light emitting diodes as light emitting elements. In yet another example, the display device 100 according to aspects of the present disclosure may be a quantum dot display device implemented with quantum dots, which are self-emitting semiconductor crystals.

The structure of each of the plurality of subpixels SP may vary according to types of the display devices 100. For example, in an example where the display device 100 is a self-emission display device including self-emitting subpixels SP, each subpixel SP may include a self-emission light emitting element, one or more transistors, and one or more capacitors.

For example, the various types of signal lines may include a plurality of data lines for transmitting data signals (also referred to as data voltages or image signals) and a plurality of gate lines for delivering gate signals (also referred to as scan signals).

The plurality of data lines and the plurality of gate lines may intersect each other. Each of the plurality of data lines may be configured to extend in a first direction. Each of the plurality of gate lines may be configured to extend in a second direction crossing the first direction.

For example, the first direction may be a column or vertical direction, and the second direction may be a row or horizontal direction. In another example, the first direction may be the row or horizontal direction, and the second direction may be the column or vertical direction.

The data driving circuit 20 may be a circuit for driving a plurality of data lines and can output data signals to the plurality of data lines. The gate driving circuit 30 may be a circuit for driving a plurality of gate lines and can output gate signals to the plurality of gate lines. The display controller 40 may be a device for controlling the data driving circuit 20 and the gate driving circuit 30, and can control driving timings for the plurality of data lines and driving timings for the plurality of gate lines.

The display controller 40 can supply at least one data driving control signal to the data driving circuit 20 to control the data driving circuit 20 and can supply at least one gate driving control signal to the gate driving circuit 30 to control the gate driving circuit 30.

The data driving circuit 20 may supply data signals to the plurality of data lines according to the driving timing control of the display controller 40. The data driving circuit 20 can receive digital image data from the display controller 40, convert the received image data into analog data signals, and output the resulting analog data signals to the plurality of data lines.

The gate driving circuit 30 may supply gate signals to the plurality of gate lines GL according to the timing control of the display controller 40. The gate driving circuit 30 can receive a first gate voltage corresponding to a turn-on level voltage and a second gate voltage corresponding to a turn-off level voltage along with several types of gate driving control signals (e.g., a start signal, a reset signal, and the like), generate gate signals, and supply the generated gate signals to the plurality of gate lines.

In one or more aspects, the data driving circuit 20 may be connected to the display panel 10 by a tape-automated-bonding (TAB) technique, may be connected to a conductive pad such as a bonding pad of the display panel 10 by a chip-on-glass (COG) technique or a chip-on-panel (COP) technique, or may be connected to the display panel 10 by a chip-on-film (COF) technique.

In one or more aspects, the gate driving circuit 30 may be connected to the display panel 10 by the tape-automated-bonding (TAB) technique, may be connected to a conductive pad such as a bonding pad of the display panel 10 by the chip-on-glass (COG) technique or the chip-on-panel (COP) technique, or may be connected to the display panel 10 by the chip-on-film (COF) technique. In one or more aspects, the gate driving circuit 30 may be disposed in the non-display area NDA of the display panel 10 by a gate-in-panel (GIP) technique. The gate driving circuit 30 may be disposed on the substrate or may be connected to the substrate. For example, in the case of the gate-in-panel (GIP) type, the gate driving circuit 30 may be disposed in the non-display area NDA of the substrate. The gate driving circuit 30 may be connected to the substrate SUB in examples where the gate driving circuit 30 is implemented by the chip-on-glass (COG) technique, the chip-on-film (COF) technique, or the like.

In one or more aspects, at least one of the data driving circuit 20 and the gate driving circuit 30 may be disposed in the display area DA of the display panel 10. In this example, at least one of the data driving circuit 20 and the gate driving circuit 30 may be configured not to overlap subpixels SP, or configured to overlap one or more, or all, of the subpixels SP.

The data driving circuit 20 may be located in, and/or electrically connected to, but not limited to, only one side or portion (e.g., an upper edge or a lower edge) of the display panel 10. In one or more aspects, the data driving circuit 20 may be located in, and/or electrically connected to, but not limited to, two sides or portions (e.g., an upper edge and a lower edge) of the display panel 10 or at least two of four sides or portions (e.g., the upper edge, the lower edge, a left edge, and a right edge) of the display panel 10 according to driving schemes, panel design schemes, or the like.

The gate driving circuit 30 may be located in, and/or electrically connected to, but not limited to, only one side or portion (e.g., a left edge or a right edge) of the display panel 10. In one or more aspects, the gate driving circuit 30 may be located in, and/or electrically connected to, but not limited to, two sides or portions (e.g., a left edge and a right edge) of the display panel 10 or at least two of four sides or portions (e.g., an upper edge, a lower edge, the left edge, and the right edge) of the display panel 10 according to driving schemes, panel design schemes, or the like.

The display controller 40 may be implemented in a separate component from the data driving circuit 20, or may be incorporated in the data driving circuit 20 and thus implemented in an integrated circuit.

The display controller 40 may be a timing controller used in the display technology or a controller or a control device capable of performing other control functions in addition to the function of the timing controller. In one or more aspects, the display controller 40 may be a controller or a control device different from the timing controller, or a circuitry or a component included in the controller or the control device. The display controller 40 may be implemented with various circuits or electronic components, such as an integrated circuit (IC), a field programmable gate array (FPGA), an application specific integrated circuit (ASIC), a processor, and/or the like.

The display controller 40 may be mounted on a printed circuit board, a flexible printed circuit, and/or the like and be electrically connected to the gate driving circuit 20 and the data driving circuit 30 through the printed circuit board, flexible printed circuit, and/or the like.

The display controller 40 can transmit signals to, and receive signals from, the data driving circuit 20 via one or more predefined interfaces. For example, such interfaces may include, a low voltage differential signaling (LVDS) interface, an embedded clock point-point interface (EPI), a serial peripheral interface (SP), and the like.

In one or more aspects, to further provide a touch sensing function in addition to an image display function, the display device 100 may include a touch panel, and a touch sensing circuit 50 configured to sense the touch panel and to detect whether a touch has been applied by a touch object, such as a finger, a pen, or the like, or detect a location (or touch coordinates) of the touch.

The touch sensing circuit 50 may include a touch driving circuit 60 configured to generate and provide touch sensing data by driving and sensing the touch panel, a touch controller 70 configured to detect whether a touch has been applied or detect a location (or touch coordinates) of the touch based on the touch sensing data, and the like.

The touch panel may include a plurality of touch electrodes. The touch panel may further include a plurality of touch routing lines for electrically connecting the plurality of touch electrodes to the touch driving circuit 60. The touch panel or all, or one or more, of touch electrodes TE may be also referred to as a touch sensor.

In one or more aspects, the touch panel may be disposed outside of the display panel 10 or inside of the display panel 10. The touch panel disposed outside of the display panel 10 may be referred to as an add-on type touch panel. The add-on type touch panel may be implemented such that the touch panel and the display panel 10 are separately manufactured and are thereafter bonded together during the process of manufacturing the display device 100. The add-on type touch panel may include a substrate and a plurality of touch electrodes on the substrate. The touch panel disposed inside of the display panel 10 may be referred to as an in-cell type touch panel or an on-cell type touch panel. The in-cell type touch panel or the on-cell type touch panel may be implemented such that the touch panel is formed inside of the display panel 10 during the process of manufacturing the display panel 10.

The touch driving circuit 60 can supply a touch driving signal to at least one of the plurality of touch electrodes and may generate touch sensing data by sensing at least one of the plurality of touch electrodes.

The touch sensing circuit 50 can perform touch sensing by a self-capacitance sensing technique, and/or a mutual-capacitance sensing technique.

Where the touch sensing circuit 50 is configured to perform touch sensing by the self-capacitance sensing technique, the touch sensing circuit 50 can perform touch sensing based on capacitance between each touch electrode and a touch object (e.g., a finger, a pen, or the like).

According to the self-capacitance sensing technique, each of the plurality of touch electrodes can serve as both a driving touch electrode and a sensing touch electrode. The touch driving circuit 60 can drive all, or one or more, of the plurality of touch electrodes and can sense all, or one or more, of the plurality of touch electrodes.

Where the touch sensing circuit 50 is configured to perform touch sensing by the mutual-capacitance sensing technique, the touch sensing circuit 50 can perform touch sensing based on capacitance between touch electrodes.

According to the mutual-capacitance sensing technique, the plurality of touch electrodes may be divided into driving touch electrodes and sensing touch electrodes. The touch driving circuit 60 can drive the driving touch electrodes and sense the sensing touch electrodes.

In one or more aspects, the touch driving circuit 60 and the touch controller 70 included in the touch sensing circuit 50 may be implemented in respective devices or be integrally implemented as a single device.

In one or more aspects, the touch driving circuit 60 and the data driving circuit 20 may be implemented in respective devices or be integrally implemented as a single device.

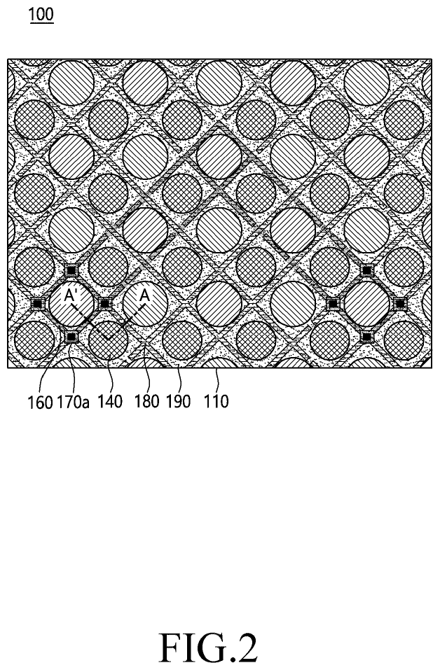

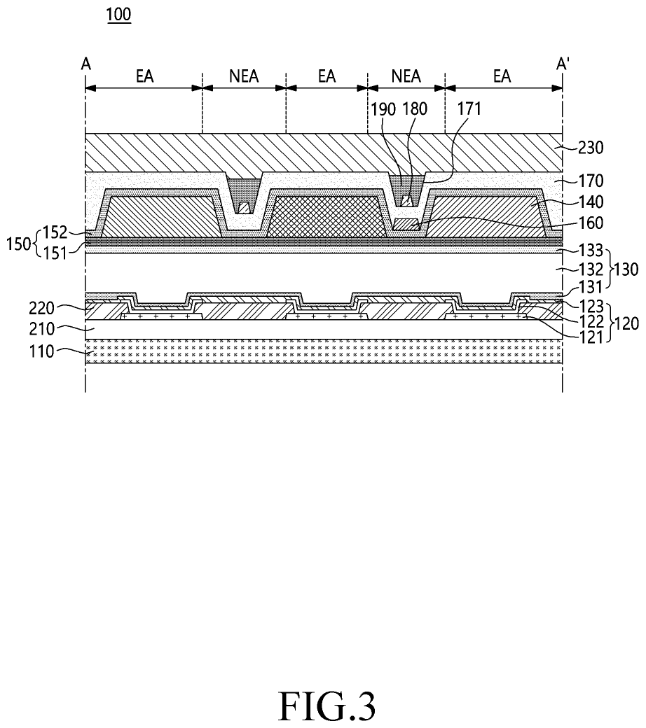

FIG. 2 is an example plan view of the display device 100 according to example embodiments of the present disclosure. FIG. 3 is an example cross-sectional view taken along line A-A′ of the display device 100 shown in FIG. 2.

As illustrated in FIGS. 2 and 3, in one or more aspects, the display device 100 may include a base substrate 110, one or more light emitting elements 120, an encapsulation layer 130, one or more color filters 140, a buffer layer 150, one or more bridges 160, at least one insulating layer 170, one or more touch sensors 180, and a black matrix 190.

The base substrate 110 may serve to support various components of the display device 100, and may include a plurality of light emitting areas EA formed in a plurality of subpixels SP and configured to present images, and a plurality of non-light emitting areas NEA each surrounding a corresponding one of the plurality of light emitting areas EA. For example, the base substrate 110 may include an insulating material, such as a glass substrate or a plastic substrate.

Each light emitting element 120 may be disposed on the base substrate 110 and may include an anode electrode 121, an emission layer 122, and a cathode electrode 123.

The anode electrode 121 may be a pixel electrode and may be independently disposed on each subpixel SP. For example, a plurality of anode electrodes 121 may be disposed on the base substrate 110 and may be disposed at locations corresponding respectively to the plurality of light emitting areas EA.

The anode electrode 121 may be a transparent electrode such as indium tin oxide (ITO), indium zinc oxide (IZO), or the like, or an opaque electrode such as copper (Cu), or the like. In one or more aspects, the anode electrode 121 may result from stacking one or more transparent electrodes and/or one or more opaque electrodes.

The emission layer 122 may be disposed on the anode electrode 121 and a bank layer 220 described later. For example, the emission layer 122 may be disposed in a corresponding light emitting area EA and a corresponding non-light emitting area NEA. In one or more aspects, the emission layer 122 may include any one of an organic emission layer, an inorganic emission layer, and a quantum dot emission layer. In one or more aspects, the emission layer 122 may include a stacked structure of an organic emission layer and a quantum dot emission layer or a stacked structure of an inorganic emission layer and a quantum dot emission layer.

The cathode electrode 123 may be disposed on the emission layer 122. For example, the cathode electrode 123 may be disposed in one or more light emitting areas EA and one or more non-light emitting areas NEA.

The encapsulation layer 130 may be disposed on light emitting elements 120 and may be configured to protect the light emitting elements 120 located under the encapsulation layer 130 from external moisture, oxygen, shock, and the like.

The encapsulation layer 130 may be disposed in light emitting areas EA and non-light emitting areas NEA, and may include one or more layers. For example, the encapsulation layer 130 may include a first encapsulation layer 131, a second encapsulation layer 132, and a third encapsulation layer 133.

The first encapsulation layer 131 may include an inorganic material and may be disposed on the cathode electrode 123. For example, the first encapsulation layer 131 may include an inorganic insulating material capable of being deposited at low temperatures, such as silicon nitride (SiNx), silicon oxide (SiOx), silicon oxynitride (SiON), aluminum oxide (Al2O3), or the like. When the first encapsulation layer 131 is deposited at a low temperature, the first encapsulation layer 131 can prevent emission layers 122, which includes organic substances vulnerable to a high temperature, from being damaged during the deposition process.

The second encapsulation layer 132 may include an organic material and may be disposed on the first encapsulation layer 131. As the second encapsulation layer 132 includes an organic material, the second encapsulation layer 132 can reduce a step difference between layers disposed under the second encapsulation layer 132. For example, the second encapsulation layer 132 may include an organic insulating material, such as acrylic resin, epoxy resin, polyimide, polyethylene, silicon oxycarbon (SiOC), or the like.

The third encapsulation layer 133 may include an inorganic material and may be disposed on the second encapsulation layer 132. For example, the third encapsulation layer 133 may include an inorganic insulating material, such as silicon nitride (SiNx), silicon oxide (SiOx), silicon oxynitride (SiON), aluminum oxide (Al2O3), or the like.

Thus, as the encapsulation layer 130 includes the plurality of layers, the penetration of moisture or oxygen from outside of the display device 100 can be minimized, and the light emitting elements 120 can thereby be effectively protected.

The color filters 140 may be disposed on the encapsulation layer 130 respectively in areas corresponding to light emitting areas EA. For example, a plurality of color filters 140 may be disposed to be spaced apart from each other on the encapsulation layer 130 and may be configured to overlap light emitting areas EA and portions of the non-light emitting areas NEA, respectively.

Each of the plurality of color filters 140 may be configured to correspond to a color of a corresponding subpixel SP. For example, where each pixel includes a red subpixel, a green subpixel, and a blue subpixel, the color filters 140 may correspondingly include red color filters 140, green color filters 140, and blue color filters 140. As the color filters 140 are disposed in areas corresponding to light emitting areas EA, respectively, the color filters 140 can serve to improve the light emitting performance of corresponding light emitting elements 120.

The buffer layer 150 may be disposed on the encapsulation layer 130 and may include a plurality layers. For example, the buffer layer 150 may include a first buffer layer 151 and a second buffer layer 152.

The first buffer layer 151 may include an insulating material and may be disposed between the color filters 140 and the encapsulation layer 130. Where this implementation is applied, at least one bridge 160 disposed on the first buffer layer 151 and light emitting elements 120 disposed under the first buffer layer 151 may be insulated from each other.

The second buffer layer 152 may include an insulating material and may cover the color filters 140 on the first buffer layer 151.

The bridge 160 may be used to electrically interconnect touch sensors 180 and may include a metal material. For example, the bridge 160 may include a metal material, such as Ti, Al, Ti, or the like, and may have a height (or thickness) of 250 to 6,000 Å.

The bridge 160 may be disposed on the buffer layer 150. For example, the bridge 160 may be disposed in a space between the color filters 140 on the second buffer layer 152. That is, the bridge 160 may be disposed in an area corresponding to one of the non-light emitting areas NEA.

The insulating layer 170 may be configured to cover the buffer layer 150 and the bridge 160, and may have at least one recessed portion 171 formed between the color filters 140. For example, the insulating layer 170 may be formed by depositing an insulating material, such as SiO2 or SiNx on the buffer layer 150. Due to a space between the color filters 140, the recessed portion 171 may be formed between the color filters 140 during the deposition process.

The touch sensor 180 may be used to detect a touch input from a user or receive input information, and may be disposed in the recessed portion 171 of the insulating layer 170. For example, the touch sensor 180 may include a metal material, such as Ti, Al, Ti, or the like, and may have a height (or thickness) of 250 to 6,000 Å.

In one or more aspects, touch sensors 180 may be electrically connected to the bridge 160 through a contact hole 170a (see FIG. 2) formed in the insulating layer 170. For example, the contact hole 170a, which is an opening area formed in a portion of the insulating layer 170, may expose the bridge 160 located in a lower portion of the insulating layer 170, and touch sensors 180 located in an upper portion of the insulating layer 170 may be electrically connected to the bridge 160 by contacting the bridge 160 through the contact hole 170a.

The black matrix 190 may cover the touch sensor 180 to block external light from being reflected by the touch sensor 180 including a metal material. For example, the black matrix 190 may include an organic material or an inorganic material having a black color. The black matrix 190 can absorb external light coming from outside of the display device 100 and can prevent or minimize the reflection of the external light by the touch sensor 180.

The black matrix 190 may be disposed in the recessed portion 171 of the insulating layer 170. For example, as the black matrix 190 is disposed between the color filters 140, color mixing between adjacent pixels can be prevented.

As a height of the black matrix 190 increases, the black matrix 190 can absorb more external light and effectively reduce the reflectance of the touch sensor 180. However, when the height of the black matrix 190 is too great, the entire height of the display device 100 may increase. To address this issue, considering a height of the color filters 140, a maximum height (or thickness) of the black matrix 190 may be preferably set to 1.0 to 2.0 μm. Here, the maximum height may refer to a height in an area in which the touch sensor 180 is not located, that is, a distance from where the black matrix 180 is in contact with the insulating layer 170 to an uppermost surface of the black matrix 180 in the cross-sectional view of FIG. 3.

In one or more aspects, a height of the recessed portion 171 disposed in an area where the bridge 160 is disposed may be formed to be smaller than that of the recessed portion 171 disposed in an area where the bridge 160 is not disposed. This is because, if the bridge 160 is located in some but not all of the spaces between the color filters 140, a step difference corresponding to a height of the bridge 160 may be formed during the deposition process of the insulating layer 170.

The maximum width of the black matrix 190 may be equal to or greater than that of the touch sensor 180. This is because, if the maximum width of the black matrix 190 is smaller than that of the touch sensor 180, the entire top surface of the touch sensor 180 may not be covered evenly, and external light thus cannot effectively be blocked from being reflected by the touch sensor 180.

In one or more aspects, the black matrix 190 may be formed to have a height smaller than that of the recessed portion 171. This is because, if the black matrix 190 is formed to have a height greater than that of the recessed portion 171, the black matrix 190 may shield the light emitting element 120, thus potentially leading to a reduction in the light emitting efficiency of the light emitting element 120.

According to the example embodiment of FIGS. 2 and 3, by adjusting the height (or thickness) of the color filters 140, the height of the recessed portion 171 (in which the touch sensor 180 is disposed) can be controlled. That is, as the height of the color filters 140 increases, the height of the recessed portions 171 may increase, and as the height of the color filters 140 decreases, the height of the recessed portions 171 may decrease. Here, the height of the color filters 140 may refer to a length or thickness in the vertical direction in the cross-sectional view of FIG. 3.

It should be noted that, where the recessed portion 171 has a greater height, a space for disposing the black matrix 190 becomes greater. Therefore, it is important or preferable to appropriately set the height of the color filters 140.

For example, the height of the color filters 140 may be set to 2.3 to 2.6 μm. This is because, if the height of the color filters 140 exceeds 2.6 μm, the entire height (or thickness) of the display device 100 may increase. On the other hand, if the height of the color filters 140 is less than 2.3 μm, the height of the black matrix 190 disposed in the recessed portion 171 may decrease, potentially leading to an increase in the reflection of light by the touch sensor 180.

In one or more aspects, the display device 100 may further include a planarization layer 210, a bank layer 220, and an overcoat layer 230.

The planarization layer 210 may serve to reduce a step difference between elements disposed under the planarization layer 210, and may be disposed between the base substrate 110 and the light emitting elements 120. For example, the planarization layer 210 may include an organic insulating material, such as acrylic resin, epoxy resin, polyamide, polyimide, polyethylene, silicon oxycarbon (SiOC), or the like.

The bank layer 220 may be disposed on the planarization layer 210 and may include openings to expose respective portions of the light emitting elements 120. For example, the bank layer 220 may be disposed between anode electrodes 121 and be configured to cover one or more edges (e.g., one or more outer edges) of each of the anode electrodes 121. Light emitted by the light emitting elements 120 can be output through the respective openings of the bank layer 220. Light emitting areas EA and non-light emitting areas NEA may be defined by the openings of the bank layer 220.

The bank layer 220 may be configured to overlap one or more touch sensors 180. For example, a touch sensor 180 may be disposed in a non-light emitting area NEA. Where the touch sensor 180 is disposed in the non-light emitting area NEA, the transmission of light emitted by a light emitting element 120 toward the touch sensor 180 including a metal material can be minimized. Thus, the image quality can be improved.

The bank layer 220 may include at least one inorganic layer or at least one organic layer. For example, the bank layer 220 may result from stacking at least one inorganic layer and/or at least one organic layer.

The overcoat layer 230 may serve to protect elements or patterns disposed under the overcoat layer 230 and may reduce a height difference or a step difference caused by such elements or patterns. The overcoat layer 230 may be configured to cover the insulating layer 170 and the black matrix 190. For example, the overcoat layer 230 may be disposed in the light emitting areas EA and the non-light emitting areas NEA, and may include an organic material, such as acrylic resin, epoxy resin, phenolic resin, polyamide resin, polyimide resin, or the like. However, the material of the overcoat layer 230 according to example embodiments of the present disclosure is not limited thereto. For example, the material of the overcoat layer 230 may include at least one inorganic material and at least one organic material.

In one or more aspects, the display device 100 may be configured to allow a touch-sensor-on-encapsulation-layer (“TOE”) process to be performed while a color-filter-on-encapsulation-layer (“COE”) process is performed. For example, to dispose the black matrix 190 with a desired target height on the touch sensor 180, after the process of depositing R, G, and B color filters 140 is performed, at least one bridge 160, the insulating layer 170, at least one touch sensor 180, and the black matrix 190 may be sequentially deposited in one or more stepped spaces between the R, G, and B color filters 140.

In this manner, when the bridge 160, the insulating layer 170, the touch sensor 180, and the black matrix 190 are deposited in the stepped space formed between the color filters 140, the black matrix 190 formed on the touch sensor 180 may have a greater thickness, compared with a case where the TOE process and the COE process are sequentially performed.

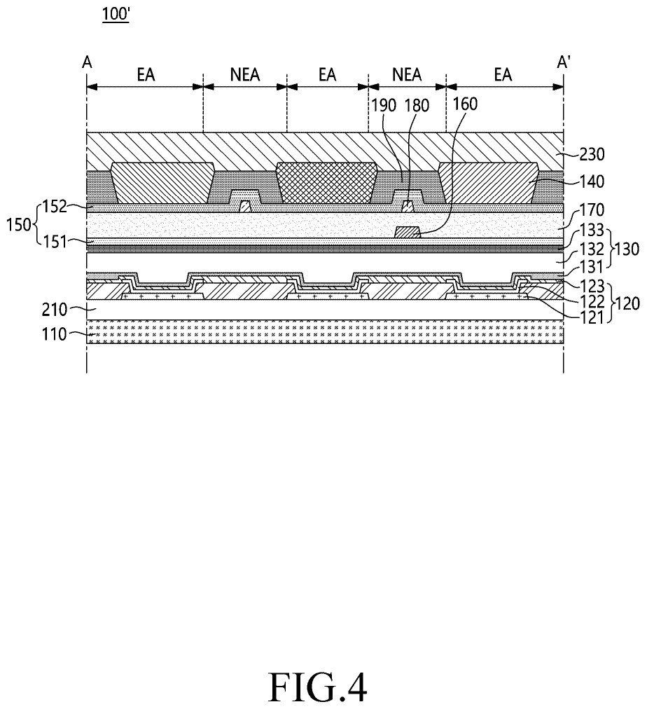

FIG. 4 is a cross-sectional view of a display device 100′ according to a comparative example in which a TOE process and a COE process are sequentially performed. The structure of the display device 100′ manufactured by the sequentially performed TOE process and COE process is discussed below.

As illustrated in FIG. 4, the process of manufacturing the display device 100′ may be performed such that, after a process of sequentially forming a planarization layer 210, one or more light emitting elements 120, and an encapsulation layer 130 on a base substrate 110 is performed, a TOE process and a COE process are performed.

For example, the TOE process may be performed such that, after a first buffer layer 151 is formed on the encapsulation layer 130, a bridge 160 may be deposited on a portion of the first buffer layer 151 corresponding to a portion of a non-light emitting area NEA. Then, an insulating layer 170 may be formed to cover the bridge 160 and the first buffer layer 151, and thereafter, a touch sensor 180 may be deposited on the insulating layer 170. Thereafter, a second buffer layer 152 may be formed to cover the insulating layer 170 and the touch sensor 180 to prevent the penetration of moisture and to insulate.

After the TOE process is completed, the COE process is performed. The COE process may be performed such that, after color filters 140 are deposited on portions of the second buffer layer 152 corresponding light emitting areas EA, a black matrix 190 is deposited in spaces between the color filters 140. After the COE process is completed, an overcoat layer 230 may be formed to cover the color filters 140 and the black matrix 190.

By these implementations, if the touch sensor 180 is formed in non-light emitting area NEA, and the second buffer layer 152 and the black matrix 190 are thereafter formed on the touch sensor 180, the black matrix 190 may be formed to have a smaller height by the combined heights of the touch sensor 180 and the second buffer layer 152. That is, as shown in FIG. 4, a central portion of the black matrix 190, which overlaps or is disposed over the touch sensor 180 and the second buffer layer 152, has a smaller height (or thickness) than edges of the black matrix 190, which does not overlap the touch sensor 180 and the insulating layer 170. Therefore, the reflection of light by the touch sensor 180 at the central portion of the black matrix 190 may increase.

In contrast, in the display device 100 according to example embodiments, e.g., as shown in FIG. 3, the color filters 140 may be formed on the encapsulation layer 130, and thereafter, the bridge 160 and insulating layer 170 with the recessed portion 171 may be formed in the stepped space between the color filters 140. Since the touch sensor 180 and the black matrix 190 are thereafter deposited in the recessed portion 171 of the insulating layer 170, the black matrix 190 may have a space corresponding to the height of the recessed portion 171.

Therefore, the black matrix 190 with a desired height may be deposited in an area where the touch sensor 180 is disposed without increasing the overall size (or thickness) of the display device 100. Thus, the reflectance of the display device 100 (e.g., the reflection of external light by the touch sensor 180) can be reduced.

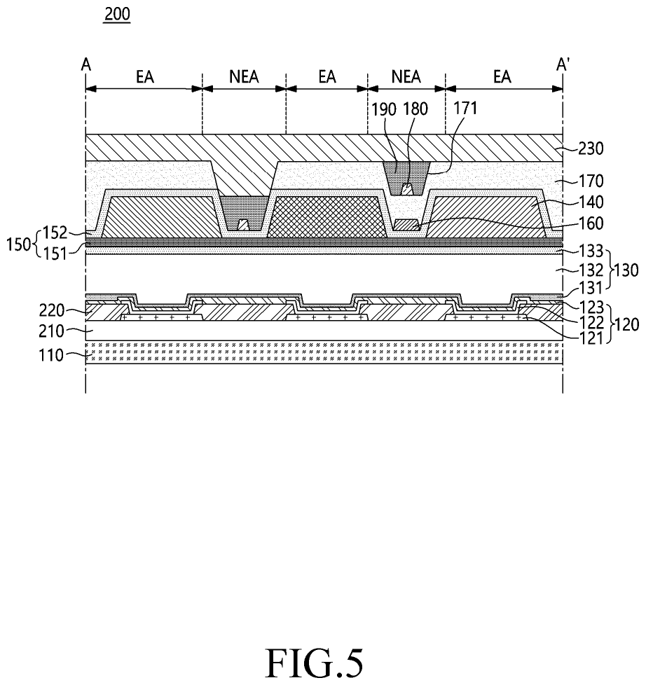

FIG. 5 is an example cross-sectional view of a display device 200 according to aspects of the present disclosure. Discussions on the example of FIG. 5 are provided by focusing on differences from the previously described examples.

As shown in FIG. 5, a recessed portion 171 formed in an insulating layer 170 of the display device 200 may be a groove-shaped recessed portion 171 with a residual material between a buffer layer 150 and the groove-shaped recessed portion 171, or may be a hole-shaped recessed portion 171 without a residual material between the buffer layer 150 and the hole-shaped recessed portion 171. For example, a recessed portion 171 in an area where a bridge 160 is disposed may have a groove shape, and another recessed portion 171 in an area where the bridge 160 is not disposed may have a hole shape. That is, the hole-shaped recessed portion 171 may be formed by removing all of the insulating layer 170 located in the recessed portion 171 in the area where the bridge 160 is not disposed.

In this manner, where the recessed portion 171 of the insulating layer 170 has a hole shape penetrating through the insulating layer 170 in the vertical direction, the black matrix 190 may have a greater height. Thus, the reflectance of the display device 200 can be reduced more effectively.

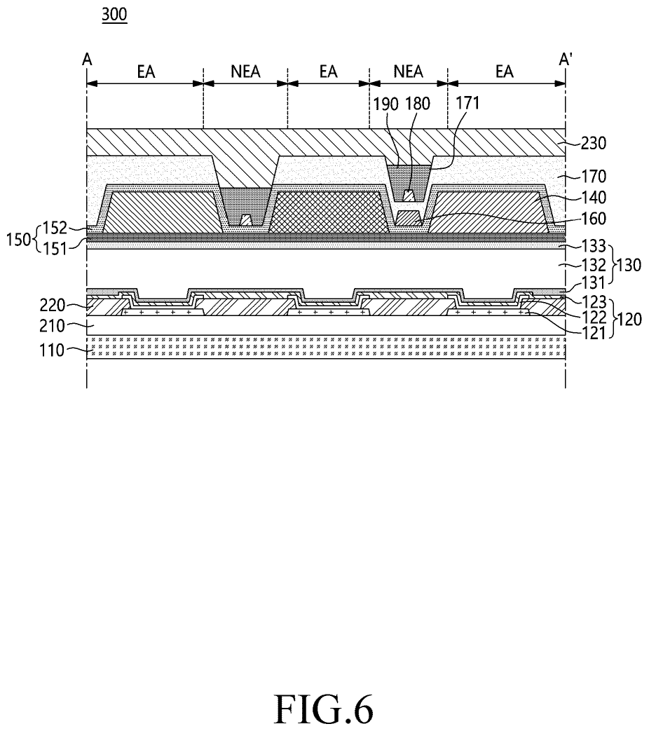

FIG. 6 is an example cross-sectional view of a display device 300 according to aspects of the present disclosure. Discussions on the example of FIG. 6 are provided by focusing on differences from the previously described examples.

As illustrated in FIG. 6, recessed portions 171 of the display device 300 may be formed such that a recessed portion 171 in an area where a bridge 160 is disposed has a groove shape, and another recessed portion 171 in an area where the bridge 160 is not disposed has a hole shape.

In this implementation, as the insulating layer 170 is deposited on a second buffer layer 152 using a halftone mask, a recessed portion 171 disposed in an area where the bridge 160 is disposed may have a height greater than the corresponding recessed portion 171 formed in the display device 200 of the FIG. 5 example. In the FIG. 6 implementation, the black matrix 190 in the recessed portion 171 where the bridge 160 is disposed may be formed to have a greater height than in the FIG. 5 implementation. Thus, the reflectance of the display device 300 can be reduced more effectively.

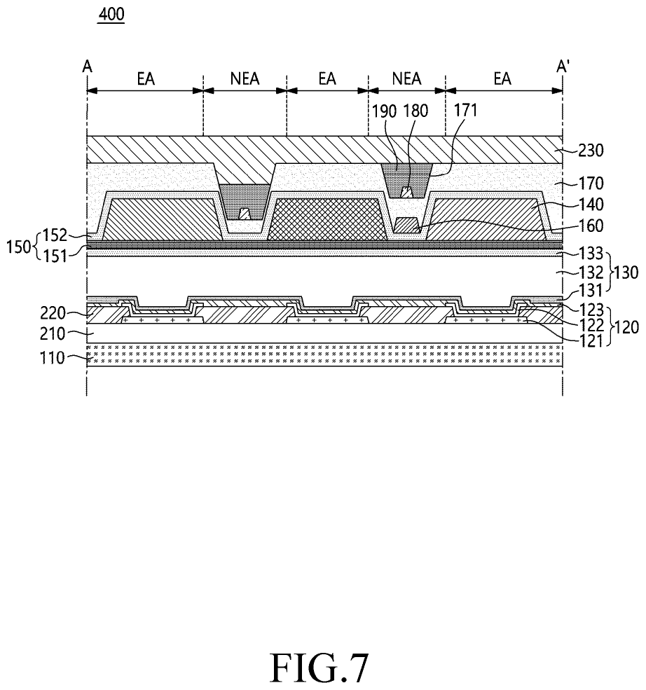

FIG. 7 is an example cross-sectional view of a display device 400 according to aspects of the present disclosure. Discussions on the example of FIG. 7 are provided by focusing on differences from the previously described examples.

As shown in FIG. 7, an insulating layer 170 of the display device 400 may include groove-shaped recessed portions 171. For example, both a recessed portion 171 in an area where the bridge 160 is disposed and another recessed portion 171 in an area where the bridge 160 is not disposed may be groove-shaped recessed portions 171 with a residual material of the insulating layer 170 at lower portions of the groove-shaped recessed portions 171.

In this implementation, the recessed portions 171 may be formed such that, after applying a halftone mask to only the area where the bridge 160 is not disposed, the insulating layer 170 is deposited on a second buffer layer 152. A height of the groove-shaped recessed portions 171 may be controlled by using the halftone mask when depositing the insulating layer 170 on the second buffer layer 152.

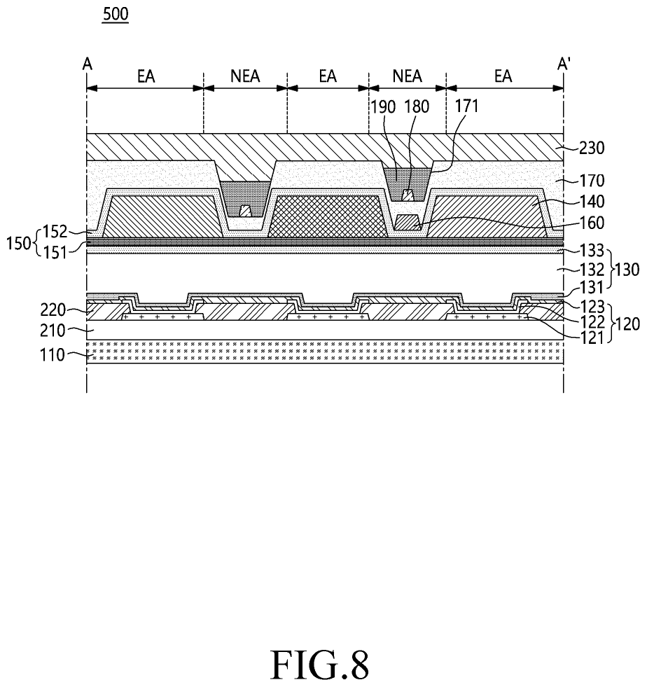

FIG. 8 is an example cross-sectional view of a display device 500 according to aspects of the present disclosure. Discussions on the example of FIG. 8 are provided by focusing on differences from the previously described examples.

As illustrated in FIG. 8, an insulating layer 170 of the display device 500 may include groove-shaped recessed portions 171. For example, both a recessed portion 171 in an area where the bridge 160 is disposed and another recessed portion 171 in an area the bridge 160 is not disposed may be groove-shaped recessed portions 171 with a residual material of the insulating layer 170 at lower portions of the groove-shaped recessed portions 171.

In this implementation, as a halftone mask is applied in both the area where the bridge 160 is disposed and the area where the bridge 160 is not disposed, the recessed portions 171 disposed in the area where the bridge 160 is disposed and in the area where the bridge 160 is not disposed may have a height greater than the corresponding recessed portions 171 formed in the display device 400 of the FIG. 7 example. Accordingly, the black matrix 190 in the recessed portion 171 where the bridge 160 is disposed may be formed to have a greater height. Thus, the reflectance of the display device 500 can be reduced more effectively.

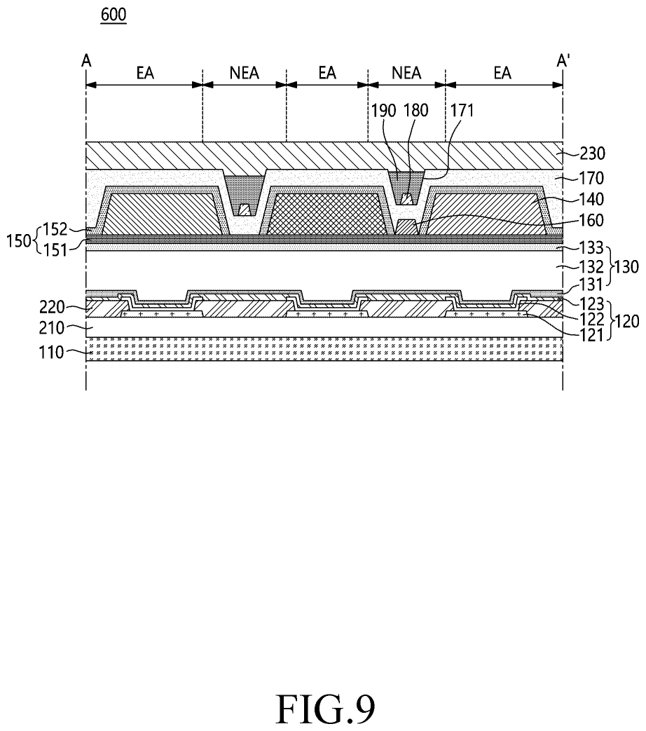

FIG. 9 is an example cross-sectional view of a display device 600 according to aspects of the present disclosure. Discussions on the example of FIG. 9 are provided by focusing on differences from the previously described examples.

As shown in FIG. 9, the display device 600 may have a structure in which a portion of a buffer layer 150 facing a recessed portion 171 is removed. Accordingly, an opening hole may be formed in the buffer layer 150 (e.g., on the second buffer layer 152 or both the first and second buffer layers 151, 152) and expose a portion of an element disposed under the second buffer layer 152 or under the buffer layer 150.

For example, as a portion of the second buffer layer 152 facing the recessed portion 171 is removed, the second buffer layer 152 may have an opening hole in at least a portion of a non-light emitting area NEA. Accordingly, a portion of a first buffer layer 151 disposed under the buffer layer 152 may be exposed through the opening hole.

In this manner, as a portion of the buffer layer 150, which is located in the non-light emitting area NEA, is removed, the recessed portion 171 may have an even greater height by the height (or thickness) of the removed buffer layer 150. Accordingly, the black matrix 190 disposed in the recessed portion 171 may be formed to have a greater height, and the reflectance of the display device 600 can thus be reduced more effectively.

Various example embodiments of the present disclosure may be briefly described as follows.

According to one or more example embodiments, a display device may include: a base substrate including a plurality of light emitting areas and a plurality of non-light emitting areas; a plurality of light emitting elements on the base substrate and respectively in the plurality of light emitting areas; an encapsulation layer on the plurality of light emitting elements; a first buffer layer on the encapsulation layer; a plurality of color filters on the first buffer layer and respectively over the plurality of light emitting areas, the plurality of color filters being spaced apart from each other; a bridge on the first buffer layer in a space between two adjacent color filters among the plurality of color filters, the bridge being disposed over one of the plurality of non-light emitting areas; an insulating layer covering the first buffer layer, the plurality of color filters, and the bridge, and including a first recessed portion over the bridge in the space between the two adjacent color filters; a touch sensor in the first recessed portion of the insulating layer; and a black matrix covering the touch sensor in the first recessed portion of the insulating layer.

In some example embodiments, each of the plurality of color filters may have a height in a range from 2.3 to 2.6 μm, and the black matrix may have a maximum height in a range from 1.0 to 2.0 μm.

In some example embodiments, the insulating layer may further include a second recessed portion in a space between two other adjacent color filters, among the plurality of color filters, where the bridge is not disposed. The first recessed portion may have a smaller height than the second recessed portion.

In some example embodiments, a maximum height of the black matrix may be greater than or equal to a maximum height of the touch sensor.

In some example embodiments, the black matrix may have a height less than or equal to a height of the first recessed portion.

In some example embodiments, the display device may further include a second buffer layer covering the plurality of color filters on the first buffer layer, the plurality of color filters being disposed between the first buffer layer and the second buffer layer.

In some example embodiments, the second buffer layer may have one or more openings exposing the first buffer layer between the plurality of color filters.

In some example embodiments, the touch sensor may be electrically connected to the bridge through a contact hole formed in the insulating layer.

In some example embodiments, the display device may further include: a planarization layer disposed between the base substrate and the plurality of light emitting elements; a bank layer on the planarization layer and having a plurality of openings each configured to expose a portion of a corresponding one of the plurality of light emitting elements; and an overcoat layer covering the insulating layer and the black matrix. The touch sensor may overlap the bank layer.

In some example embodiments, the insulating layer may further include a second recessed portion in a space between two other adjacent color filters, among the plurality of color filters, where the bridge is not disposed. Each of the first recessed portion and the second recessed portion may be one of: a groove-shaped recessed portion with the insulating layer disposed between the black matrix and the first buffer layer; and a hole-shaped recessed portion through the insulating layer so that the insulating layer is not disposed between the black matrix and the first buffer layer.

In some example embodiments, the first recessed portion of the insulating layer may be the groove-shaped recessed portion, and the second recessed portion of the insulating layer may be the hole-shaped recessed portion.

According to one or more example embodiments, a display device may include: a substrate including a plurality of light emitting areas and a plurality of non-light emitting areas respectively between the light emitting areas; a first buffer layer over the substrate; a plurality of color filters on the first buffer layer and respectively over the light emitting areas, the color filters being spaced apart from each other; a bridge on the first buffer layer in a space between two adjacent color filters among the color filters; an insulating layer covering the first buffer layer, the color filters, and the bridge, and having a first recessed portion over the bridge in the space between the two adjacent color filters; a touch sensor in the first recessed portion of the insulating layer; and a black matrix covering the touch sensor in the first recessed portion of the insulating layer.

In some example embodiments, the display device may further include a plurality of light emitting elements on the substrate and respectively in the light emitting areas, and an encapsulation layer on the light emitting elements and under the first buffer layer. The non-light emitting areas may respectively surround the light emitting areas in a plan view. The bridge may be disposed over one of the non-light emitting areas.

In some example embodiments, the display device may further include a second buffer layer on the first buffer layer and the color filters, the color filters being disposed between the first buffer layer and the second buffer layer.

In some example embodiments, the second buffer layer may have one or more openings exposing the first buffer layer between the plurality of color filters.

In some example embodiments, each of the color filters may have a height in a range from 2.3 to 2.6 μm, and the black matrix may have a maximum height in a range from 1.0 to 2.0 μm.

In some example embodiments, the insulating layer may further include a second recessed portion in a space between two other adjacent color filters, among the color filters, where the bridge is not disposed. The first recessed portion may have a smaller height than the second recessed portion.

In some example embodiments, the insulating layer may further include a second recessed portion in a space between two other adjacent color filters, among the color filters, where the bridge is not disposed. The first recessed portion may be a groove-shaped recessed portion with the insulating layer disposed between the black matrix and the first buffer layer. The second recessed portion may be a hole-shaped recessed portion through the insulating layer so that the insulating layer is not disposed between the black matrix and the first buffer layer.

In some example embodiments, a maximum height of the black matrix may be greater than or equal to a maximum height of the touch sensor.

In some example embodiments, the black matrix may have a height less than or equal to a height of the first recessed portion.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents.

What is claimed is:

1. A display device, comprising:
a base substrate including a plurality of light emitting areas and a plurality of non-light emitting areas;
a plurality of light emitting elements on the base substrate and respectively in the plurality of light emitting areas;
an encapsulation layer on the plurality of light emitting elements;
a first buffer layer on the encapsulation layer;
a plurality of color filters on the first buffer layer and respectively over the plurality of light emitting areas, the plurality of color filters being spaced apart from each other;
a bridge on the first buffer layer in a space between two adjacent color filters among the plurality of color filters, the bridge being disposed over one of the plurality of non-light emitting areas;
an insulating layer covering the first buffer layer, the plurality of color filters, and the bridge, and including a first recessed portion over the bridge in the space between the two adjacent color filters;
a touch sensor in the first recessed portion of the insulating layer; and
a black matrix covering the touch sensor in the first recessed portion of the insulating layer.

2. The display device of claim 1, wherein:
each of the plurality of color filters has a height in a range from 2.3 to 2.6 μm; and
the black matrix has a maximum height in a range from 1.0 to 2.0 μm.

3. The display device of claim 1, wherein:
the insulating layer further includes a second recessed portion in a space between two other adjacent color filters, among the plurality of color filters, where the bridge is not disposed; and
the first recessed portion has a smaller height than the second recessed portion.

4. The display device of claim 1, wherein a maximum height of the black matrix is greater than or equal to a maximum height of the touch sensor.

5. The display device of claim 1, wherein the black matrix has a height less than or equal to a height of the first recessed portion.

6. The display device of claim 1, further comprising a second buffer layer covering the plurality of color filters on the first buffer layer, the plurality of color filters being disposed between the first buffer layer and the second buffer layer.

7. The display device of claim 6, wherein the second buffer layer has one or more openings exposing the first buffer layer between the plurality of color filters.

8. The display device of claim 1, wherein the touch sensor is electrically connected to the bridge through a contact hole formed in the insulating layer.

9. The display device of claim 1, further comprising:
a planarization layer disposed between the base substrate and the plurality of light emitting elements;
a bank layer on the planarization layer and having a plurality of openings each configured to expose a portion of a corresponding one of the plurality of light emitting elements; and
an overcoat layer covering the insulating layer and the black matrix,
wherein the touch sensor overlaps the bank layer.

10. The display device of claim 1, wherein:
the insulating layer further includes a second recessed portion in a space between two other adjacent color filters, among the plurality of color filters, where the bridge is not disposed; and
each of the first recessed portion and the second recessed portion is one of:
a groove-shaped recessed portion with the insulating layer disposed between the black matrix and the first buffer layer; and
a hole-shaped recessed portion through the insulating layer so that the insulating layer is not disposed between the black matrix and the first buffer layer.

11. The display device of claim 10, wherein:
the first recessed portion of the insulating layer is the groove-shaped recessed portion; and
the second recessed portion of the insulating layer is the hole-shaped recessed portion.

12. A display device, comprising:
a substrate including a plurality of light emitting areas and a plurality of non-light emitting areas respectively between the light emitting areas;
a first buffer layer over the substrate;
a plurality of color filters on the first buffer layer and respectively over the light emitting areas, the color filters being spaced apart from each other;
a bridge on the first buffer layer in a space between two adjacent color filters among the color filters;
an insulating layer covering the first buffer layer, the color filters, and the bridge, and having a first recessed portion over the bridge in the space between the two adjacent color filters;
a touch sensor in the first recessed portion of the insulating layer; and
a black matrix covering the touch sensor in the first recessed portion of the insulating layer.

13. The display device of claim 12, further comprising:
a plurality of light emitting elements on the substrate and respectively in the light emitting areas; and
an encapsulation layer on the light emitting elements and under the first buffer layer,
wherein the non-light emitting areas respectively surround the light emitting areas in a plan view, and
wherein the bridge is disposed over one of the non-light emitting areas.

14. The display device of claim 12, further comprising:
a second buffer layer on the first buffer layer and the color filters, the color filters being disposed between the first buffer layer and the second buffer layer.

15. The display device of claim 14, wherein the second buffer layer has one or more openings exposing the first buffer layer between the plurality of color filters.

16. The display device of claim 12, wherein:
each of the color filters has a height in a range from 2.3 to 2.6 μm; and
the black matrix has a maximum height in a range from 1.0 to 2.0 μm.

17. The display device of claim 12, wherein:
the insulating layer further includes a second recessed portion in a space between two other adjacent color filters, among the color filters, where the bridge is not disposed; and
the first recessed portion has a smaller height than the second recessed portion.

18. The display device of claim 12, wherein:
the insulating layer further includes a second recessed portion in a space between two other adjacent color filters, among the color filters, where the bridge is not disposed;
the first recessed portion is a groove-shaped recessed portion with the insulating layer disposed between the black matrix and the first buffer layer; and
the second recessed portion is a hole-shaped recessed portion through the insulating layer so that the insulating layer is not disposed between the black matrix and the first buffer layer.

19. The display device of claim 12, wherein a maximum height of the black matrix is greater than or equal to a maximum height of the touch sensor.

20. The display device of claim 12, wherein the black matrix has a height less than or equal to a height of the first recessed portion.
